(19) United States
(12) Patent Application Publication
(10) Pub. No.: US 2025/0357066 A1
(43) Pub. Date: Nov. 20, 2025

(54) ELECTRON BEAM METROLOGY HAVING A SOURCE ENERGY SPREAD WITH FILTERED TAILS

(71) Applicant: KLA Corporation, Milpitas, CA (US)

(72) Inventors: Xinrong Jiang, Palo Alto, CA (US); Youfei Jiang, Milpitas, CA (US)

(21) Appl. No.: 18/668,112

(22) Filed: May 17, 2024

(51) Int. Cl. H01J 37/05; H01J 37/147

(52) U.S. Cl. CPC H01J 37/05; H01J 37/1471; H01J 37/1472

(57) ABSTRACT

A first Wien filter and a second Wien filter are disposed in the path of a charged particle beam directed toward a workpiece on a stage. An assembly is disposed in the path of the charged particle beam between the first Wien filter and the second Wien filter. Part of the charged particle beam is blocked by the assembly. The charged particle beam may be an electron beam.

### FIELD OF THE DISCLOSURE

This disclosure relates to metrology of workpieces, such as semiconductor wafers.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a workpiece like a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Metrology processes are used at various steps during semiconductor manufacturing to monitor and control the process. Metrology processes are different than inspection processes in that, unlike inspection processes in which defects are detected on wafers, metrology processes are used to measure one or more characteristics of the wafers that cannot be determined using existing inspection tools. Metrology processes can be used to measure one or more characteristics of wafers such that the performance of a process can be determined from the one or more characteristics. For example, metrology processes can measure a dimension (e.g., line width, thickness, etc.) of features formed on the wafers during the process. In addition, if the one or more characteristics of the wafers are unacceptable (e.g., out of a predetermined range for the characteristic(s)), the measurements of the one or more characteristics of the wafers may be used to alter one or more parameters of the process such that additional wafers manufactured by the process have acceptable characteristic(s).

In previous metrology systems, the electron source with either a thermal field emission (TFE) emitter or a cold field emission (CFE) emitter generated electrons. These electrons were accelerated to certain beam energies (e.g., 10 kV) and then focused by lenses (e.g., an objective lens (OL)) onto the workpiece (e.g., a semiconductor wafer). The electron beam focused on the workpiece was characterized by a landing energy (LE), a numeric aperture (NA), and a spot size. The NA was the beam half angle β. An alternative expression of the spot size is the resolution, which reflects the image-forming quality. The emitter could be characterized by the source energy spread (ΔE) and angular intensity (J) or brightness (B). The values of ΔE and J with a TFE electron source were normally much larger than those with a CFE. For examples, the ΔE in a 0.3 μm (radius) TFE tip (emitter) was about 1.2 eV when J is 0.45 mA/sr, and ΔE in a 0.1 μm (radius) CFE tip was about 0.4 eV when J is 0.03 mA/sr.

The previous systems could include electron beam splitter, which separates the secondary electrons (SE) from the primary electrons (PE). An example of an electron beam splitter is a Wien filter, which includes an orthogonal electrostatic deflection field (WF_E) and magnetic deflection field (WF_B). The PEs from the electron source were balanced by the Wien filter E×B forces, and the SEs emitted from wafer were deflected by the Wien filter at an angle ρ to a detector.

New application trends of electron beam metrologies must meet challenging optical conditions with low landing energies (e.g., 100˜1000 eV), low extracting fields (e.g., 0˜1500 V/mm), and wide range of beam currents (BC) (e.g., low beam currents from 0.01˜1.0 nA and high beam currents from 1.0˜100 nA). The low beam current regime may be used with after-develop inspection (ADI), defect review, 2D critical dimension uniformity (CDU) measurements, or critical dimension scanning electron microscopy (CD-SEM). The high beam current regime may be used for hot spot inspection, physical defect inspection, or voltage contrast (VC) inspection. With ADI metrology for example, a low landing energy around 200 eV is used with low extracting field around 500 V/mm to avoid the shrinkage of high numeric aperture (HiNA) EUV resists.

The electron optical resolution with the conditions of low landing energies and low extracting fields is chromatically limited. The energy spread with an electron source (e.g., a TFE source) may generate an axial chromatic aberration blur through focusing lenses including stigmators, an off-axis chromatic aberration blur through deflecting scanners, and a transverse chromatic blur through beam-splitting Wien filters. This can be expressed as follows.

$${d}_{c} ∝ {C}_{c} \frac{Δ E}{LE}$$

ΔE is the source energy spread measured with full width at half maximum (FWHM), LE is the landing energy of an electron beam, C_{c} and de are respectively the chromatic aberration coefficient and chromatic aberration blur of one of the four optical operations (i.e., lens image-forming, stigmator astigmatism-correcting, deflector beam-scanning, or Wien filter beam-splitting). Normally, the coefficient C_{c} increases with LE, so the chromatic blur de increases with the source energy spread ΔE absolutely. Chromatic blurs not only limit the image resolutions, but also degrade the image contrast under influence of the long tails of an electron beam spot because the source energy spread has a Gaussian distribution.

A CFE source may offer narrowed source energy spread (e.g., approximately 0.4 eV) to reduce the chromatic blurs and improve resolution. However, an electron beam metrology apparatus with a CFE source provides high resolution for uses with low beam currents (e.g., 0.01˜1.0 nA). A CFE source is generally worse than a TFE source when used with high beam currents (e.g., 1.0˜100 nA) because of the fairly low angular intensity of a CFE source. To obtain high beam currents with low angular intensity, the optical magnification may be large and the gun lens aberrations may be magnified into the workpiece image, causing poor resolutions in high beam current uses. A CFE source also typically needs extreme ultra-high vacuum below 1×10⁻¹¹ millibar, and a self-cleaning system for removing tiny amounts of residual gas. If a single atom adheres to the CFE tip, it can partially block the emission of electrons, resulting in unstable operations.

Therefore, improved systems and techniques are needed.

### BRIEF SUMMARY OF THE DISCLOSURE

A system is provided in a first embodiment. The system includes a source that generates a charged particle beam; a stage configured to hold a workpiece in a path of the charged particle beam; a first Wien filter disposed in the path of the charged particle beam between the source and the stage; a second Wien filter disposed in the path of the charged particle beam between the first Wien filter and the stage; and an assembly that defines a slit. The assembly is disposed in the path of the charged particle beam between the first Wien filter and the second Wien filter. Part of the charged particle beam is blocked by the assembly.

The charged particle beam may be an electron beam and the source may be an electron source. In an instance, the electron source is a thermal field emission source.

The charged particle beam can be focused in a plane of the slit by the first Wien filter. The charged particle beam can be focused in an image plane by the second Wien filter.

The system can include a gun lens disposed in the path of the charged particle beam between the source and the first Wien filter; a first condenser lens disposed in the path of the charged particle beam between the gun lens and the first Wien filter; and a second condenser lens disposed in the path of the charged particle beam between the second Wien filter and the stage.

In an instance, the system further includes a beam limiting aperture assembly that defines a beam limiting aperture and a column assembly that defines an aperture. The beam limiting aperture assembly is disposed in the path of the charged particle beam between the gun lens and the first condenser lens. The column assembly is disposed in the path of the charged particle beam between the beam limiting aperture assembly and the first condenser lens. The path of the charged particle beam can be configured to have a crossover between the beam limiting aperture assembly and the column assembly.

In an instance, the path of the charged particle beam can be configured to be telecentric between the first condenser lens and the second condenser lens.

In an instance, the path of the charged particle beam can be configured to have a crossover between the second condenser lens and the stage.

In an instance, the system further includes a first deflector disposed in the path of the charged particle beam between the second condenser lens and the stage and a second deflector disposed in the path of the charged particle beam between the first deflector and the stage. A third Wien filter may be disposed in the path of the charged particle beam between the second condenser lens and the first deflector. A fourth Wien filter may be disposed in the path of the charged particle beam between the first deflector and the second deflector.

The slit may be dimensions from 1 micron to 2 microns.

A method is provided in a second embodiment. The method includes generating a charged particle beam with a source. The charged particle beam is directed toward a workpiece disposed on a stage. The charged particle beam is directed through a first Wien filter disposed in the path of the charged particle beam downstream of the source. The charged particle beam is directed through an assembly that defines a slit. The assembly is disposed in the path of the charged particle beam downstream of the first Wien filter. Part of the charged particle beam is blocked by the assembly. The charged particle beam is directed through a second Wien filter disposed in the path of the charged particle beam downstream of the assembly. The charged particle beam impacts the workpiece along the path of the charged particle beam downstream of the second Wien filter.

The charged particle beam may be an electron beam and the source may be an electron source.

The charged particle beam may have a beam current from 0.01 nA to 100 nA.

The first Wien filter and the second Wien filter may be coaxial.

In an instance, the charged particle beam can be focused in the plane of the slit using the first Wien filter. The charged particle beam can be focused in an image plane using the second Wien filter.

The charged particle beam can be directed through a gun lens disposed in the path of the charged particle beam between the source and the first Wien filter. The charged particle beam can be directed through a first condenser lens disposed in the path of the charged particle beam between the gun lens and the first Wien filter. The charged particle beam can be directed through a second condenser lens disposed in the path of the charged particle beam between the second Wien filter and the stage.

In an instance, the charged particle beam can be directed through a beam limiting aperture assembly that defines a beam limiting aperture. The beam limiting aperture assembly may be disposed in the path of the charged particle beam between the gun lens and the first condenser lens. The charged particle beam can be directed through a column assembly that defines an aperture. The column assembly may be disposed in the path of the charged particle beam between the beam limiting aperture assembly and the first condenser lens.

In an instance, the path of the charged particle beam can be configured to have a crossover between the beam limiting aperture assembly and the column assembly.

In an instance, the path of the charged particle beam can be configured to be telecentric between the first condenser lens and the second condenser lens.

In an instance, the path of the charged particle beam can be configured to have a crossover between the second condenser lens and the stage.

In an instance, the charged particle beam can be deflected using a first deflector disposed in the path of the charged particle beam between the second condenser lens and the stage. The charged particle beam can be deflected using a second deflector disposed in the path of the charged particle beam between the first deflector and the stage. The charged particle beam can be directed through a third Wien filter disposed in the path of the charged particle beam between the second condenser lens and the first deflector. The charged particle beam can be directed through a fourth Wien filter disposed in the path of the charged particle beam between the first deflector and the second deflector.

### DESCRIPTION OF THE DRAWINGS

For a fuller understanding of the nature and objects of the disclosure, reference should be made to the following detailed description taken in conjunction with the accompanying drawings, in which:

FIG. 1 is a diagram of an embodiment of energy filtering and image formation with a dual Wien filter monochromator in accordance with the present disclosure;

FIG. 2 is a diagram of an embodiment of a charged particle beam metrology system with a monochromator in accordance with the present disclosure;

FIG. 3 is an optics diagram for a charged particle beam metrology system with a monochromator in accordance with the present disclosure;

FIGS. 4(a)-4(b) show performance of source filter energy filtering with a dual Wien filter monochromator in accordance with the present disclosure;

FIGS. 5(a)-5(b) show axial resolution improvement with a dual Wien filter monochromator in accordance with the present disclosure;

FIGS. 6(a)-6(b) show image uniformity across a large-scan field of view with a dual Wien filter monochromator in accordance with the present disclosure;

FIG. 7 is a diagram of another embodiment of a charged particle beam metrology system with a monochromator in accordance with the present disclosure;

FIG. 8 shows exemplary Wien filter-induced transverse chromatic blur at a workpiece;

FIG. 9 shows exemplary transverse chromatic correction with dual Wien filters;

FIG. 10 shows exemplary correction of residual transverse chromatic blurs with a monochromator in accordance with the present disclosure;

FIG. 11 is a diagram of another embodiment of a charged particle beam metrology system with a monochromator for high beam current operations in accordance with the present disclosure;

FIG. 12 is an embodiment of a Wien filter; and

FIG. 13 is a flow chart of an embodiment of a method in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments disclosed herein can use a straight monochromator in a straight optical column for improved alignments and to filter off the tails of a TFE source energy spread. After energy-filtering, the charged particles (e.g., electrons) are image-formed at the workpiece with largely reduced chromatic blurs while performing lens-focusing, deflector-scanning, and Wien filter beam-splitting simultaneously. The monochromator may be switched from on for low beam current uses and off for high beam current uses, or vice versa. Embodiments disclosed herein improve resolution of a metrology system.

Embodiments disclosed herein can narrow source energy spread and potentially replace a CFE electron source with a TFE electron source. With a monochromator in a TFE electron beam metrology column, the source energy spread can be 3×-reduced from, for example, 1.2 eV to 0.4 eV. This is the same level of the energy spread as a CFE source, but the TFE source tends to have higher angular intensities.

Embodiments disclosed herein can improve image resolution. With a 3×-reduced energy spread by a monochromator, the axial resolution is improved due to the dominant chromatic blurs being reduced. The axial chromatic blurs may be generated with the beam-focusing by lenses, astigmatism-correcting by stigmators, and beam-splitting by Wien filters.

Embodiments disclosed herein can improve image uniformity. The 3×-reduced source energy spread with a monochromator may either improve image uniformity across a given scan field of view (FOV) or, given an image uniformity requirement, raise the throughput of a review or inspection operation by increasing FOVs and/or reducing stage motions.

Embodiments disclosed herein can be used with a large range of beam currents. A CFE-based electron beam metrology apparatus may be better with low beam currents (e.g., 0.01˜1.0 nA), but worse than a TFE apparatus in high beam currents (e.g., 1.0˜100 nA). A monochromator-based electron beam metrology apparatus can be switched for different applications with low beam currents and with high beam currents. High resolutions in both low and high beam currents uses may be achieved. Embodiments disclosed herein also can be used with various column condition changes (e.g., landing energies, extracting fields, or beam currents) for various applications of electron beam metrologies.

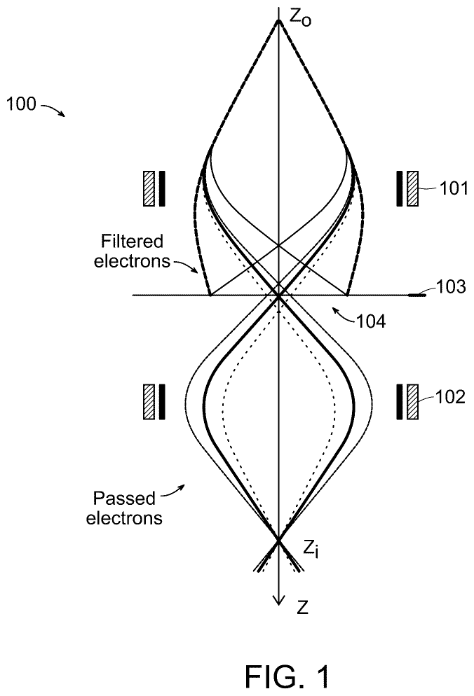

Dual Wien filters can be part of a monochromator with a controllable energy-filtering resolution by using different sizes of a slit, as shown in the metrology system 100 of FIG. 1. The first Wien filter 101 and second Wien filter 102 are coaxially arranged along the path of the charged particle beam (e.g., electron beam) that extends along the direction z. An assembly 103 that defines a slit 104 is positioned between the first Wien filter 101 and second Wien filter 102 along the path of the particle beam. Part of the charged particle beam can be blocked by the assembly 103. Electron ray-tracing simulations demonstrate the image-forming relation from zₒ (the object) to zᵢ (the image). The first Wien filter 101 and second Wien filter 102 can act as focusing lenses. The electrons emitted from zₒ are focused in the slit plane by the first Wien filter 101 and then focused in the image plane zᵢ by the second Wien filter 102. If the electrons from zₒ have an energy spread (non-monochromatic) ΔE, the energy dispersion of the electrons is displayed in the slit plane through the first Wien filter 101 focusing. The slit 104 with an appropriate size stops the electrons with larger energy spread and lets the electrons with smaller energy spread pass through, such that the electrons are filtered with an energy resolution defined by the size of the slit 104.

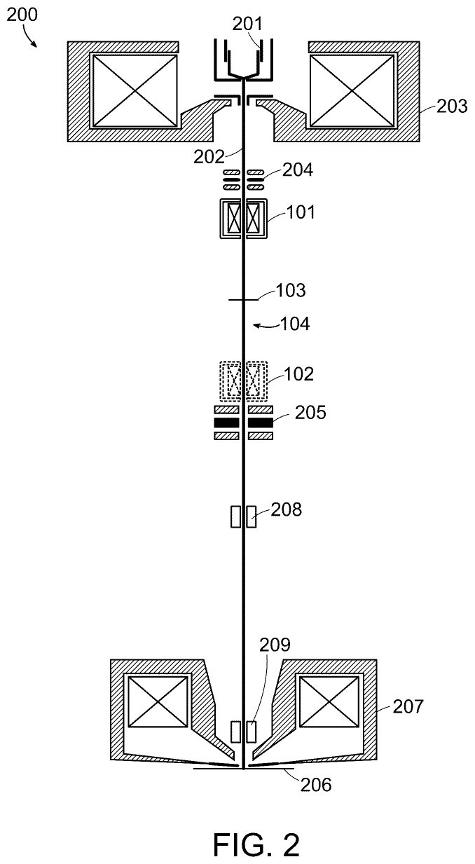

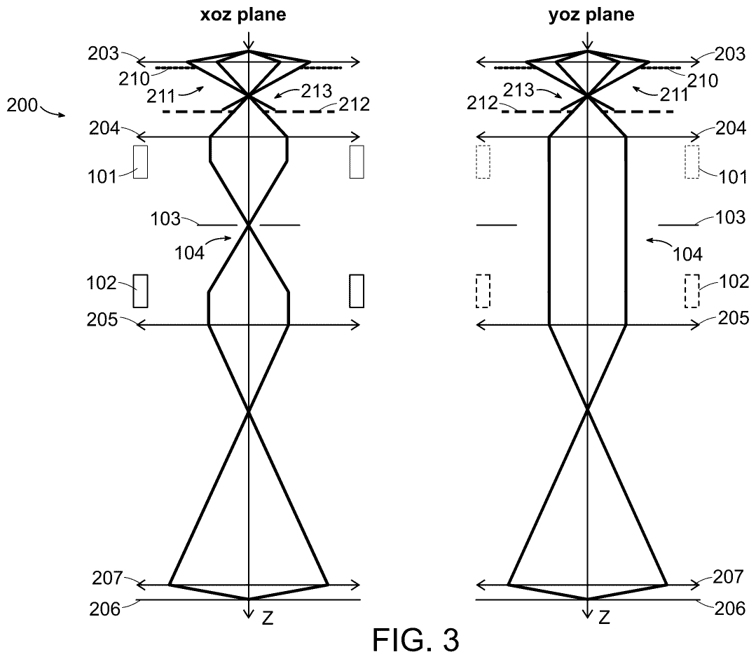

FIG. 2 shows a first embodiment of a metrology system 200 equipped with a dual Wien filter monochromator. A source 201 (e.g., TFE source) emits a charged particle beam 202 (e.g., electrons) and these electrons are accelerated by the anode and focused by the gun lens 203, which can be a magnetic lens that includes pole pieces and coils. The metrology system 200 may only include one charged particle beam 202. The dual Wien filter monochromator in FIG. 1 with the first Wien filter 101, assembly 103, and second Wien filter 102 is positioned along the path of the charged particle beam 202 between the first condenser lens 204 and second condenser lens 205. The gun lens 203 is positioned in the path of the charged particle beam 202 between the source 201 and the first Wien filter 101. The gun lens 203 can include a gun acceleration lens, a gun magnetic lens, and the anode. The first condenser lens 204 is positioned in the path of the charged particle beam 202 between the gun lens 203 and the first Wien filter 101. The second condenser lens 205 is positioned in the path of the charged particle beam 202 between the second Wien filter 102 and a stage 206. The stage 206 is configured to hold a workpiece (e.g., a semiconductor wafer) in a path of the charged particle beam 202. The spot size (resolution) may be minimized by selecting an optimal numerical aperture (NA) through focusing the second condenser lens 205, which is shown in FIG. 3.

An objective lens 207 in FIG. 2 includes pole pieces and coils. The objective lens 207 is positioned in the path of the charged particle beam 202 between the second condenser lens 205 and the stage 206. A dual-deflector scanning system is positioned in the path of the charged particle beam 202 between the second condenser lens 205 and the objective lens 207. The dual-deflector scanning system includes a first deflector 208 and a second deflector 209. The second deflector 209 may be positioned in the objective lens 207. A dual-deflector scanning system can improve large FOV scanning by minimizing the off-axis aberrations and distortion. The charged particle beam 202 is first deflected an angle by the first deflector 208 and the second deflector 209 deflects the charged particle beam 202 back in an opposite direction and then directs the charged particle beam 202 passing through the center of the combined objective lens 207. Through optimizing the relative voltages and relative rotation angles between the first deflector 208 and second deflector 209, all off-axis deflection aberrations and distortion can be minimized across a large FOV scan.

FIG. 3 shows the operation optics of the metrology system 200 of FIG. 2 in the xoz plane and the corresponding yoz plane. The gun lens 203 is the combined lens that includes the gun acceleration lens (i.e., the electrostatic section from the TFE emitter to the anode) and gun magnetic lens (i.e., the gun lens coils and gun pole pieces). A beam limiting aperture assembly 210 that defines a beam limiting aperture 211 is positioned in the path of the charged particle beam 202 between the gun lens 203 and the first condenser lens 204. A column assembly 212 that defines an aperture 213 is positioned in the path of the charged particle beam 202 between the beam limiting aperture assembly 210 and the first condenser lens 204. The column assembly 212 and/or the aperture assembly 210 can block part of the charged particle beam 202 to limit beam current.

The beam limiting aperture 211 following the gun lens 203 is used to select raw beam currents. The aperture 213 is arranged in the front of the first condenser lens 204 to select the beam currents by changing the gun lens 203 excitation and moving the beam crossover between the beam limiting aperture 211 and aperture 213. The beam currents may be lower than the raw beam current. The charged particle beam 202 between first condenser lens 204 and second condenser lens 205 may be telecentric in yoz plane and focused in xoz plane. The xoz and yoz planes are perpendicular to each other. The energy filtering in xoz plane is similar to FIG. 1. In the xoz plane, a telecentric charged particle beam 202 focused by the first condenser lens 204 enters into the first Wien filter 101 and a telecentric beam leaves the second Wien filter 102 such that the energy-filtered beam is focused by the second condenser lens 205 onto the same crossover point in both the xoz and yoz planes. The beam crossover below the second condenser lens 205 becomes the object of the objective lens 207 and is image-formed onto the workpiece on the stage 206.

As shown in FIG. 3, the path of the charged particle beam 202 can have a crossover between the beam limiting aperture assembly 210 and the column assembly 212. The path of the charged particle beam 202 also can have a crossover between the second condenser lens 205 and the stage 206. The charged particle beam 202 may be telecentric between the first condenser lens 204 and the second condenser lens 205.

Assume that the monochromator conducts energy filtering in xoz plane, which means that the Wien filter electrostatic force is balanced to the magnetic force in xoz plane (the first Wien filter 101 and second Wien filter 102 are shown in solid lines). In the yoz plane the electrostatic and magnetic forces are different (the first Wien filter 101 and second Wien filter 102 are shown in dotted lines). The slit 104 in the xoz plane can have dimensions from approximate 1-2 microns. The slit 104 in the yoz plane can have an open size to let all electrons pass through. The Wien filter electrode-voltage for electrostatic force and coil-current for magnetic force may be varied with beam energies. For a 10 kV electron beam energy-filtering, hundreds of Volts of voltage and hundreds of milli-Amperes of current may be applied.

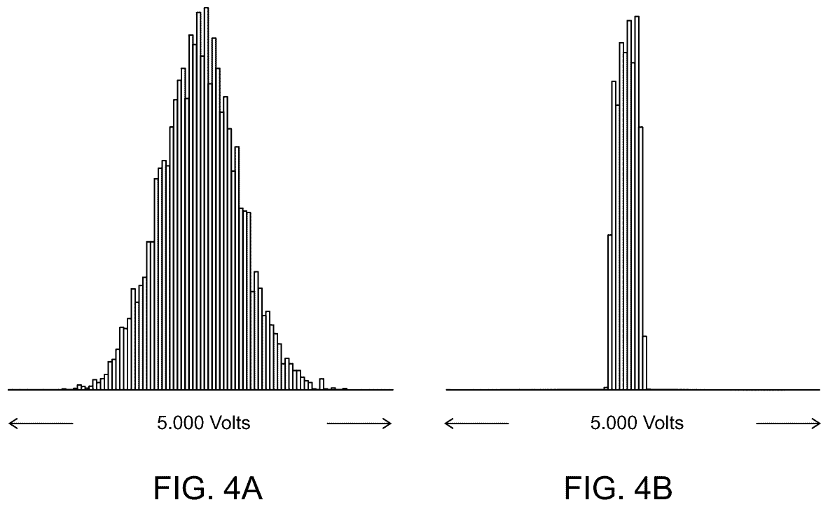

FIGS. 4(a)-4(b) show the performance of source energy filtering resolution. Conventionally speaking, the chromatic aberration blurs were no longer dominant over the resolution if the source energy spread was >3× narrowed. Accordingly, an appropriate size of the slit 104 in FIG. 2 or FIG. 3 is used to meet an approximate 3× ΔE-reduction in the energy-filtering simulations shown in FIGS. 4(a)-4(b) (e.g., around 1 micron with a 10 kV electron beam or around 2 microns with a 5 kV electron beam). A too narrow slit may cause loss of useful beam currents without improving resolutions more efficiently.

FIG. 4(a) shows an initial energy spread with a TFE source (e.g., ΔE is 1.2 eV and J is 0.45 mA/sr with a tip of 0.3 microns). With the dual-Wien monochromator turned on in FIG. 2, the source energy spread distribution cut off the tails, as shown in FIG. 4(b). The full width at half maximum (FWHM) energy spread in FIG. 4(b) is now around 3× reduced compared to the FWHM energy spread in FIG. 4(a).

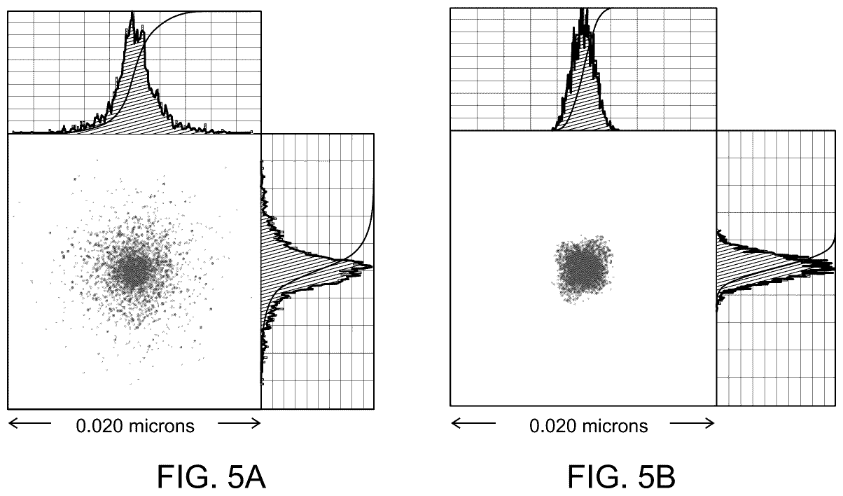

A Monte Carlo simulation method is used to demonstrate the resolution changes before and after the dual-Wien monochromator is employed for the optics in FIG. 3, as shown the results in FIGS. 5(a)-5(b). Without a monochromator (i.e., the first Wien filter 101 and the second Wien filter 102 are off), FIG. 5(a) shows the electron distribution in the least confused plane in workpiece with the source energy spread in FIG. 4(a). With the monochromator (i.e., the first Wien filter 101 and the second Wien filter 102 are on), FIG. 5(b) shows the electron distribution in the least confused plane again with the source energy spread in FIG. 4(a) but being energy-filtered in FIG. 4(b). The spot size may be measured with the current-rise curves (the overlaid lines) in the x-projection plot and y-projection plot. For example, the spot size in FIG. 5(b) is around 1.6 nm with a 20-80% current-rise measurement. Note that the scaling width is 20 nm in FIGS. 5(a)-5(b). FIGS. 5(a)-5(b) indicates that a dual-Wien monochromator improves the axial resolution and cuts off the tails of the electron beam profile for improving the image contrasts.

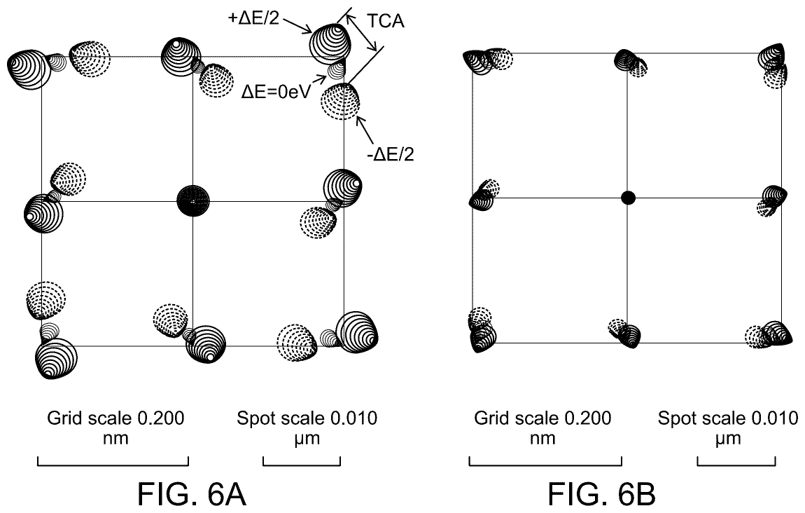

With a dual-Wien monochromator, not only is the axial resolution improved, but the image uniformity across a large scan field of view (FOV) also is ameliorated, as can be demonstrated in FIGS. 6(a)-6(b). When the electron beam is scanned across a field of view by the first deflector 204 and second deflector 205 in FIG. 2, off-axis aberration blurs and distortion occur. The off-axis aberrations (a.k.a. deflection aberrations) include the coma blur, field curvature (FC) blur, astigmatism (Stig) blur, and transverse chromatic aberration (TCA) blur. The distortion, field curvature blur, and astigmatism are all geometrical and can be corrected in electron optics. The coma blur is relatively small and not normally corrected without a measurable resolution impact. Accordingly, the TCA is uncorrectable but mainly responsible for the image uniformity issues.

FIGS. 6(a)-6(b) show the changes of the image uniformity across a large scan FOV before (FIG. 6(a)) and after (FIG. 6(b)) an embodiment of a dual-Wien monochromator is employed. During scanning across an FOV by the first deflector 204 and second deflector 205, each electron with a specific energy is deflected to different positions at the workpiece such that a transverse chromatic aberration is generated, as shown in FIG. 6(a), where the ΔE is the source energy spread. Accordingly, the narrower the source energy spread ΔE, the smaller the transverse chromatic aberration will be or the better the image uniformity will be.

Computer simulations demonstrate the changes of image uniformity in FIGS. 6(a)-6 (b). FIG. 6(a) shows the simulation and plot for the optics in FIG. 2 without a monochromator. The resolution and image uniformity in FIG. 6(a) are limited and/or dominated by the source energy spread in FIG. 4(a). FIG. 6(b) shows the improvements of the resolution and image uniformity for the optics in FIG. 2 with a dual-Wien monochromator. Because the objective lens 207, the first deflector 204, and the second deflector 205 are all arranged below the monochromator, the narrowed electron energy spread in FIG. 4(b) is applied for both image-forming and image-scanning with improved resolution and image uniformity in FIG. 6(b). A narrowed source energy spread also can improve the axial spot size.

The transverse chromatic aberration (TCA) may be expressed as follows.

$$TCA ∝ FOV ( \frac{Δ E}{LE} )$$

The transverse chromatic aberration increases linearly with the scan field of view (FOV) and energy spread ΔE. Accordingly, the operating throughput of an electron beam review or inspection may be raised by increasing FOV while the energy spread is reduced with a monochromator. A larger FOV may reduce the motions of the stage that holds a workpiece. The stage motion can be mechanical and, therefore, time-consuming.

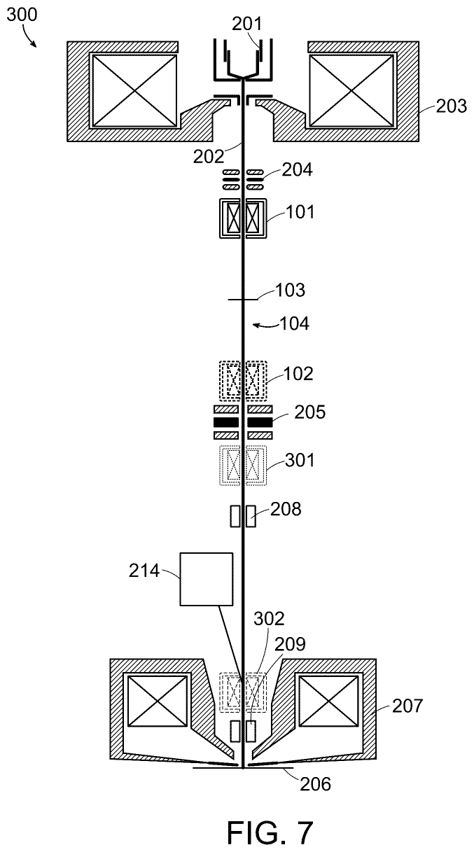

FIG. 7 shows an embodiment of construction for a metrology system 300 with high resolutions. A third Wien filter 301 is positioned in the path of the charged particle beam 202 between the second condenser lens 205 and the first deflector 208. A fourth Wien filter 302 is positioned in the path of the charged particle beam 202 between the first deflector 208 and the second deflector 209. To split secondary electrons (SE) from primary electrons (PE), a Wien filter deflects the SE beam to a detector while balancing the PE beam on the optical axis or the fourth Wien filter 302 in FIG. 7. The fourth Wien filter 302 can direct secondary electrons to the detector 214. The third Wien filter 301 and the fourth Wien filter 302 may have the same structure as the first Wien filter 101 and the second Wien filter 102, but different voltages or excitations may be applied.

The SE-collection Wien filter (i.e., the fourth Wien filter 302 in FIG. 7) can be strong enough to deflect the SE beam a relatively large angle. For a given (fixed) beam energy and source energy spread (ΔE), the energy dispersion generated by an electrostatic deflector is different from that by a magnetic deflector. A strong Wien filter (i.e., the fourth Wien filter 302 in FIG. 7) can introduce a transverse chromatic (TC) blur due to the difference of the energy dispersions between electrostatic and magnetic deflection fields.

The energy dispersions in one Wien filter may be compensated by another Wien filter. For example, the energy dispersions with the third Wien filter 301 in FIG. 7 can compensate the energy dispersions with the fourth Wien filter 302. If the electron beam between the second condenser lens 205 and the objective lens 207 is telecentric, the energy dispersions between the third Wien filter 301 and the fourth Wien filter 302 may be compensated by each other if both the third Wien filter 301 and the fourth Wien filter 302 have the identical designs and reverse polarities. In practice the beam profile in between the second condenser lens 205 and the objective lens 207 is not telecentric, and designs for the third Wien filter 301 and the fourth Wien filter 302 may be different too, but there can be optimal power settings for the third Wien filter 301 to best compensate the fourth Wien filter 302. This scheme is referred to as dual Wien filter transverse chromatic corrections. The rationale of a dual Wien filter monochromator can be different from that of a dual Wien filter transverse chromatic corrector.

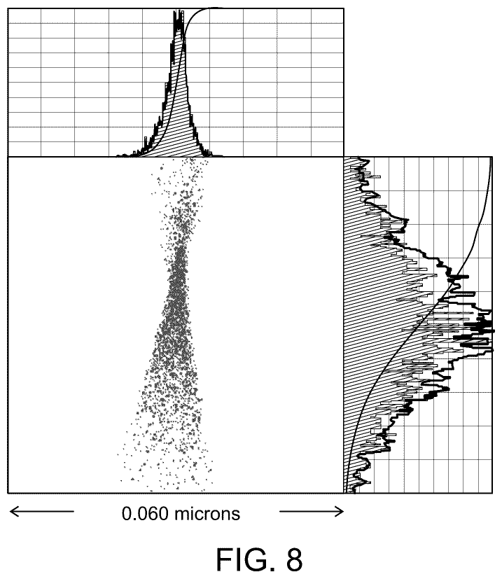

Without applying the monochromator and the third Wien filter 301, FIG. 8 shows the transverse chromatic blur induced by the fourth Wien filter 302 in the electron beam metrology apparatus in FIG. 7. The power strengths of the fourth Wien filter 302 are configured to deflect the SE beam to the detector. The source energy spread in FIG. 4(a) is used to simulate the transverse chromatic blur in FIG. 8. The resolution is poor due to the energy dispersions generated with fourth Wien filter 302.

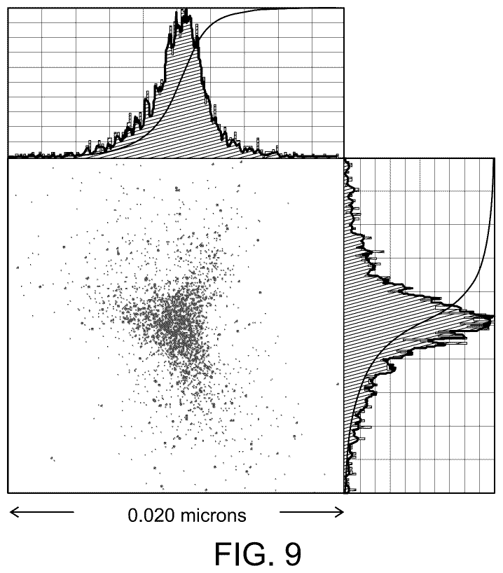

FIG. 9 shows that most of the transverse chromatic blur in FIG. 8 are corrected by using the third Wien filter 301 and fourth Wien filter 302 together to constitute a dual Wien filter transverse chromatic blur corrector. With the transverse chromatic blur correction rationale described herein, the simulation for FIG. 9 uses the source energy spread in FIG. 4(a). Without employing the dual-Wien monochromator, the spot size in FIG. 9 is still larger than the axial spot size in FIG. 5(a) (which have the same scaling), meaning that certain residual transverse chromatic blurs may persist.

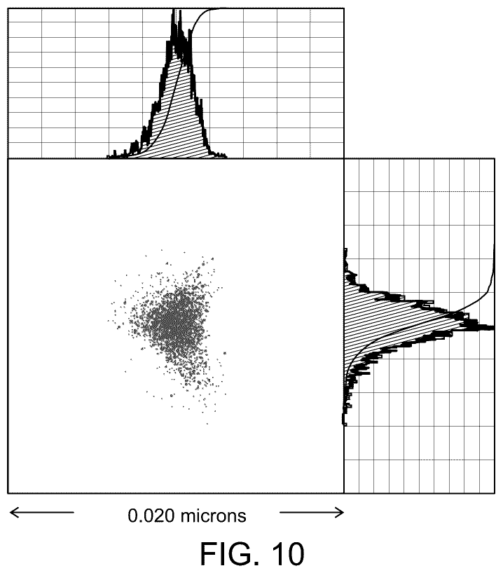

The residual transverse chromatic blurs in FIG. 9 may be removed using the dual Wien filter monochromator in FIG. 7, as can be shown in FIG. 10. In the simulations for FIG. 10, both the dual-Wien monochromator and the dual-Wien transverse chromatic blur corrector in FIG. 7 are applied simultaneously. As described previously, the source energy spread in FIG. 4(a) is filtered into the narrowed energy spread in FIG. 4(b) by the monochromator, so the electrons moving through the dual-Wien transverse chromatic blur corrector will generate fewer (e.g., 3X-reduced) energy dispersions. With the transverse chromatic blur correction on the energy-spread-reduced electrons, the residual transverse chromatic blurs in FIG. 9 are mostly removed, as seen in FIG. 10, in which the spot size is now almost as small as that in FIG. 5(b).

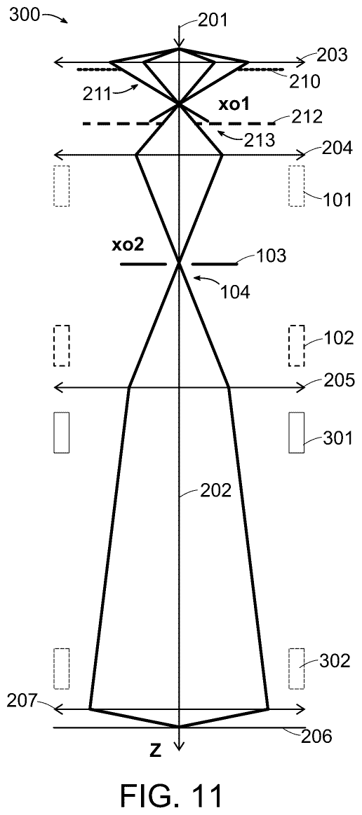

The metrology system can be used for both low beam current and high beam current applications. FIG. 11 shows the optics of the metrology system 300 in FIG. 7. The operation with the optics in FIG. 11 is for the uses of high beam currents, such as for 2D physical defect inspections with, for example, beam currents from approximately 1-15 nA (e.g., 5 nA) and 2D voltage contrast inspections with, for example, beam currents from approximately 15-100 nA (e.g., 20 nA).

In high beam current uses, the chromatic blurs are no longer dominant over resolution. Instead, the source image and the blurs of Coulomb interactions between electrons are more weighted. Accordingly, the monochromator in FIG. 11 is off (i.e., the first Wien filter 101 and second Wien filter 102 are not powered). All the charged particles selected by the aperture 213 are focused on the narrow slit to let them pass through without losing the beam currents. The beam profile between the second condenser lens 205 and objective lens 206 may have a crossover like FIG. 3 or without a crossover like FIG. 11. The dual Wien filter transverse chromatic blur corrector (the third Wien filter 301 and the fourth Wien filter 302) can be applied for the correcting the energy dispersions with the source energy spread in FIG. 4(a).

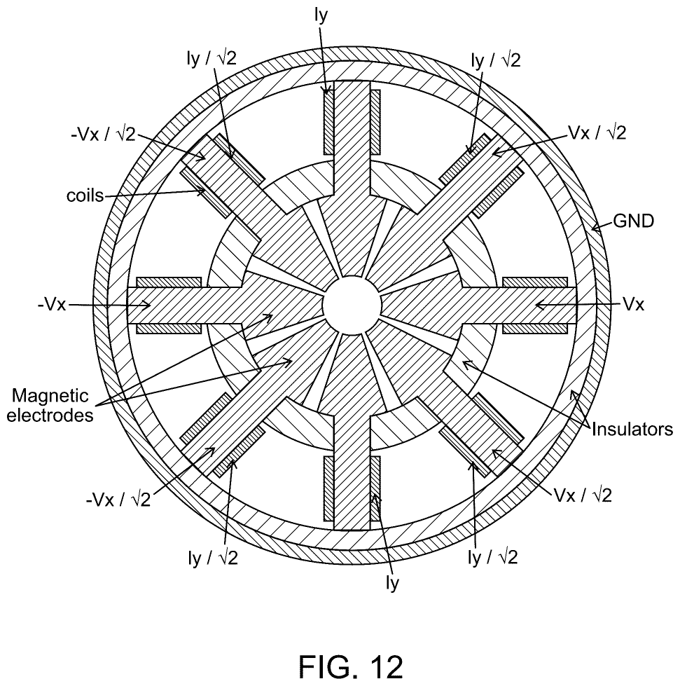

FIG. 12 shows the construction of a Wien filter with homogeneous deflection fields. The design shown in FIG. 12 can apply to the first Wien filter 101, second Wien filter 102, third Wien filter 301, and/or fourth Wien filter 302. Both the electrostatic deflection field and magnetic deflection field are generated by an octupole deflector. The eight-piece magnetic electrodes are used as both electrostatic octupole and magnetic octupole. An electrostatic or magnetic octupole deflector powered in the way shown in FIG. 12 may eliminate the 3rd, 5th, 9th, 11th, or other higher orders of components of the deflection field expanded in series. The electrostatic force powered by the deflection voltage Vx is in +x-axis direction and the magnetic force powered the deflection current Iy is in-x-axis direction. The coils can be wire-wound around the magnetic electrodes. The magnetic deflection field in +y-axis direction can be generated with the current Iy passing through the coils. The octupoles can be held and shielded by the insulators and ground conductor as shown in FIG. 12.

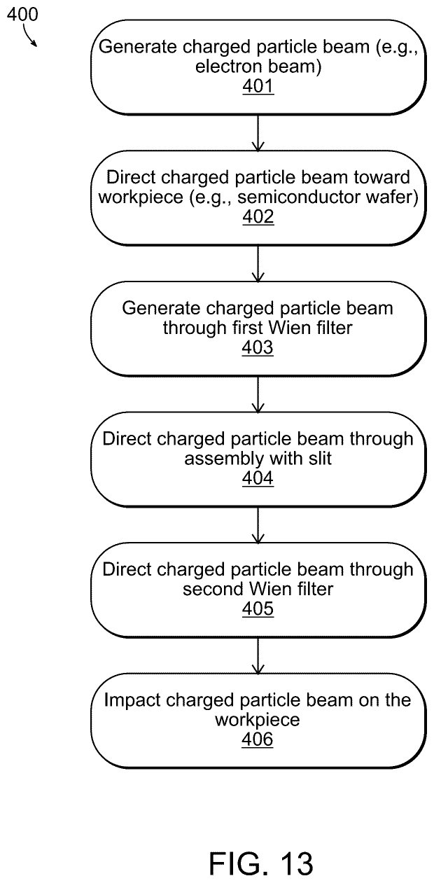

FIG. 13 is a flow chart of an embodiment of a method 400. The method 400 can use any of the systems disclosed herein. In the method 400, a charged particle beam (e.g., an electron beam) is generated with a source (e.g., an electron source) at 401. The charged particle beam is directed toward a workpiece (e.g., a semiconductor wafer) on a stage at 402. The charged particle beam is directed through a first Wien filter downstream of the source at 403. The charged particle beam is then directed through an assembly that defines a slit downstream of the first Wien filter at 404 and through a second Wien filter downstream of the assembly at 405. Part of the charged particle beam is blocked by the assembly. The charged particle beam impacts the workpiece at 406. The workpiece is downstream of the second Wien filter. The charged particle beam can have a beam current from 0.01 nA to 100 nA. The first Wien filter and the second Wien filter can be coaxial. In an instance, the charged particle beam is focused in the plane of the slit using the first Wien filter and focused in an image plane using the second Wien filter. The method 400 can apply to any of the system embodiments disclosed herein.

In an embodiment, the charged particle beam can be directed through a gun lens disposed between the source and the first Wien filter; a first condenser lens disposed between the gun lens and the first Wien filter; and a second condenser lens disposed between the second Wien filter and the stage. The charged particle beam also can be directed through a beam limiting aperture assembly that defines a beam limiting aperture between the gun lens and the first condenser lens and a column assembly that defines an aperture, wherein the column assembly is between the beam limiting aperture assembly and the first condenser lens. The path of the charged particle beam can be configured to have a crossover between the beam limiting aperture assembly and the column assembly. The path of the charged particle beam also can be configured to be telecentric between the first condenser lens and the second condenser lens. The charged particle beam further can be configured to have a crossover between the second condenser lens and the stage.

In an embodiment, the charged particle beam is deflected using a first deflector disposed in the path of the charged particle beam between the second condenser lens and the stage and a second deflector disposed in the path of the charged particle beam between the first deflector and the stage. The charged particle beam also can be directed through a third Wien filter between the second condenser lens and the first deflector and a fourth Wien filter between the first deflector and the second deflector.

While disclosed with electron beams, the embodiments disclosed herein can apply to other charged particles beams. Thus, ion beams (e.g., helium ion beams) also can benefit from the embodiments disclosed herein. The source can be an electron beam source, an ion beam source, or other devices.

Other types of workpieces besides semiconductor wafers may be used. For example, the workpiece may be used to manufacture LEDs, solar cells, magnetic discs, flat panels, or polished plates. Defects on other objects also may be classified using techniques and systems disclosed herein.

Although the present disclosure has been described with respect to one or more particular embodiments, it will be understood that other embodiments of the present disclosure May be made without departing from the scope of the present disclosure. Hence, the present disclosure is deemed limited only by the appended claims and the reasonable interpretation thereof.

What is claimed is:

1. A system comprising:
a source that generates a charged particle beam;
a stage configured to hold a workpiece in a path of the charged particle beam;
a first Wien filter disposed in the path of the charged particle beam between the source and the stage;
a second Wien filter disposed in the path of the charged particle beam between the first Wien filter and the stage; and
an assembly that defines a slit, wherein the assembly is disposed in the path of the charged particle beam between the first Wien filter and the second Wien filter, wherein part of the charged particle beam is blocked by the assembly.

2. The system of claim 1, wherein the charged particle beam is an electron beam and the source is an electron source.

3. The system of claim 2, wherein the electron source is a thermal field emission source.

4. The system of claim 1, wherein the charged particle beam is focused in a plane of the slit by the first Wien filter, and wherein the charged particle beam is focused in an image plane by the second Wien filter.

5. The system of claim 1, further comprising:
a gun lens disposed in the path of the charged particle beam between the source and the first Wien filter;
a first condenser lens disposed in the path of the charged particle beam between the gun lens and the first Wien filter; and
a second condenser lens disposed in the path of the charged particle beam between the second Wien filter and the stage.

6. The system of claim 5, further comprising:
a beam limiting aperture assembly that defines a beam limiting aperture, wherein the beam limiting aperture assembly is disposed in the path of the charged particle beam between the gun lens and the first condenser lens; and
a column assembly that defines an aperture, wherein the column assembly is disposed in the path of the charged particle beam between the beam limiting aperture assembly and the first condenser lens.

7. The system of claim 6, wherein the path of the charged particle beam is configured to have a crossover between the beam limiting aperture assembly and the column assembly.

8. The system of claim 5, wherein the path of the charged particle beam is configured to be telecentric between the first condenser lens and the second condenser lens.

9. The system of claim 5, wherein the path of the charged particle beam is configured to have a crossover between the second condenser lens and the stage.

10. The system of claim 5, further comprising:
a first deflector disposed in the path of the charged particle beam between the second condenser lens and the stage; and
a second deflector disposed in the path of the charged particle beam between the first deflector and the stage.

11. The system of claim 10, further comprising:
a third Wien filter disposed in the path of the charged particle beam between the second condenser lens and the first deflector; and
a fourth Wien filter disposed in the path of the charged particle beam between the first deflector and the second deflector.

12. The system of claim 1, wherein the slit has dimensions from 1 micron to 2 microns.

13. A method comprising:
generating a charged particle beam with a source;
directing the charged particle beam toward a workpiece disposed on a stage;
directing the charged particle beam through a first Wien filter disposed in the path of the charged particle beam downstream of the source;
directing the charged particle beam through an assembly that defines a slit, wherein the assembly is disposed in the path of the charged particle beam downstream of the first Wien filter, and wherein part of the charged particle beam is blocked by the assembly;
directing the charged particle beam through a second Wien filter disposed in the path of the charged particle beam downstream of the assembly; and
impacting the charged particle beam on the workpiece along the path of the charged particle beam downstream of the second Wien filter.

14. The method of claim 13, wherein the charged particle beam is an electron beam and the source is an electron source.

15. The method of claim 13, wherein the charged particle beam has a beam current from 0.01 nA to 100 nA.

16. The method of claim 13, wherein the first Wien filter and the second Wien filter are coaxial.

17. The method of claim 13, further comprising:
focusing the charged particle beam in the plane of the slit using the first Wien filter; and
focusing the charged particle beam in an image plane using the second Wien filter.

18. The method of claim 13, further comprising:
directing the charged particle beam through a gun lens disposed in the path of the charged particle beam between the source and the first Wien filter;
directing the charged particle beam through a first condenser lens disposed in the path of the charged particle beam between the gun lens and the first Wien filter; and
directing the charged particle beam through a second condenser lens disposed in the path of the charged particle beam between the second Wien filter and the stage.

19. The method of claim 18, further comprising:
directing the charged particle beam through a beam limiting aperture assembly that defines a beam limiting aperture, wherein the beam limiting aperture assembly is disposed in the path of the charged particle beam between the gun lens and the first condenser lens; and
directing the charged particle beam through a column assembly that defines an aperture, wherein the column assembly is disposed in the path of the charged particle beam between the beam limiting aperture assembly and the first condenser lens.

20. The method of claim 19, wherein the path of the charged particle beam is configured to have a crossover between the beam limiting aperture assembly and the column assembly.

21. The method of claim 18, wherein the path of the charged particle beam is configured to be telecentric between the first condenser lens and the second condenser lens.

22. The method of claim 18, wherein the path of the charged particle beam is configured to have a crossover between the second condenser lens and the stage.

23. The method of claim 18, further comprising:
deflecting the charged particle beam using a first deflector disposed in the path of the charged particle beam between the second condenser lens and the stage; and
deflecting the charged particle beam using a second deflector disposed in the path of the charged particle beam between the first deflector and the stage.

24. The method of claim 23, further comprising:
directing the charged particle beam through a third Wien filter disposed in the path of the charged particle beam between the second condenser lens and the first deflector; and
directing the charged particle beam through a fourth Wien filter disposed in the path of the charged particle beam between the first deflector and the second deflector.
